(19) United States
(12) Patent Application Publication
(10) Pub. No.: US 2009/0072349 A1
(43) Pub. Date: Mar. 19, 2009

(54) Semiconductor device and method of manufacturing the same

(75) Inventors: Yong-Suk Tak, Seoul (KR); Jung-Hee Chung, Suwon-si (KR); Jin-Yong Kim, Seoul (KR); Wan-Don Kim, Yongin-si (KR); Young-Sun Kim, Suwon-si (KR)

Correspondence Address: HARNESS, DICKEY & PIERCE, P.L.C., P.O. BOX 8910, RESTON, VA, 20195, US

(73) Assignee: Samsung Electronics, Co., Ltd.

(21) Appl. No.: 12/232,145

(22) Filed: Sep. 11, 2008

(30) Foreign Application Priority Data
Sep. 13, 2007 (KR) 10-2007-0093291

(51) Int. Cl. H01L 29/92; H01L 21/02

(52) U.S. Cl. 257/532; 438/381; 257/E29.343; 257/E21.008

(57) ABSTRACT

Example embodiments provide a semiconductor device and a method of manufacturing the same. A semiconductor device according to example embodiments may include a lower electrode including a first lower electrode and a second lower electrode, and the second lower electrode may be formed on at least a part of the first lower electrode using a material different from the first lower electrode. A dielectric film may be formed on at least a part of the second lower electrode and a first upper electrode may be formed on the dielectric film.

### FOREIGN PRIORITY STATEMENT

This application claims priority under 35 U.S.C. §119 to Korean Patent Application No. 10-2007-0093291 filed on Sep. 13, 2007 in the Korean Intellectual Property Office, the entire contents of which are incorporated herein by reference.

### BACKGROUND

1. Field

Example embodiments provide a semiconductor device and a method of manufacturing the same.

2. Related Art

Due to demand for integrated memory devices, the design rule of the memory devices has been reduced, and the operations of the memory devices may be performed at higher speeds. A capacitor that stores information of a Dynamic Random Access Memory (DRAM) device may be required to have the same or a greater capacitance in a smaller area. Accordingly, technologies have been studied to increase the capacitance of the capacitor.

Methods that increase the capacitance of the capacitor in a limited area may include a method that reduces the thickness of a dielectric film of the capacitor or a method that increases the effective area of an electrode by forming the electrode in a three-dimensional shape.

There may be a limitation to increasing the capacitance of the capacitor by reducing the thickness of a dielectric film or by forming an electrode in a three-dimensional shape. Accordingly, higher dielectric constant materials having a Perovskite structure have been studied.

However, when a dielectric film having the Perovskite crystal structure is formed on an electrode, contact interface characteristics between the electrode and the dielectric film may deteriorate.

### SUMMARY

Example embodiments provide a semiconductor device that may include a capacitor having improved electrical characteristics.

Example embodiments provide a method of manufacturing a semiconductor device that may include a capacitor having improved electrical characteristics.

A semiconductor device according to example embodiments may include a first lower electrode and a second lower electrode, the second lower electrode on at least a part of the first lower electrode and including a material different from the first lower electrode, a dielectric film on at least a part of the second lower electrode, and a first upper electrode on the dielectric film.

The thickness of the second lower electrode may be in the range of approximately 3 to 70 Å, the range of approximately 3 to 50 Å, or the range of approximately 10 to 50 Å, for example.

The second lower electrode may be formed of SrRuO₃, and the dielectric film may be formed of (BaSr)TiO₃ or SrTiO₃.

The first lower electrode may be formed of Pt, Ru, or Ir, or may comprise a single film selected from the group consisting of Pt, Ru, Ir, PtO, RuO₂, IrO₂, Ti, TiN, W, WN, Ta, TaN, HfN, ZrN, TiAlN, TaSiN, TiSiN, and TaAlN, a composite film of two or more of Pt, Ru, Ir, PtO, RuO₂, IrO₂, Ti, TiN, W, WN, Ta, TaN, HfN, ZrN, TiAlN, TaSiN, TiSiN, and TaAlN, or a laminate film of Pt, Ru, Ir, PtO, RuO₂, IrO₂, Ti, TiN, W, WN, Ta, TaN, HfN, ZrN, TiAlN, TaSiN, TiSiN, or TaAlN.

The second lower electrode may comprise a conductive oxide that contains at least one material with a Perovskite crystal structure.

The second lower electrode may consist of a material selected from the group including SrRuO₃, CaRuO₃, (BaSr)RuO₃, LaNiO₃, (LaSr)CoO₃, (LaSr)MgO₃, and (LaSr)SnO₃.

The dielectric film may comprise a dielectric material having a Perovskite crystal structure.

The dielectric film may consist of a material selected from the group including (BaSr)TiO₃, SrTiO₃, BaTiO₃, (PbZr)TiO₃, and (PbLaZr)TiO₃.

A semiconductor device may comprise a first lower electrode and a second lower electrode, the second lower electrode on at least a part of the first lower electrode and including a material different from the first lower electrode, a dielectric film on at least a part of the second lower electrode, and a first upper electrode and a second upper electrode, the second upper electrode on the dielectric film and the first upper electrode on the second upper electrode.

The semiconductor device may further comprise a lower structure including a conductive plug, wherein the first lower electrode is on the conductive plug, the dielectric film is on the first lower electrode, and the second lower electrode is between a side surface of the first lower electrode and the dielectric film, and between the first lower electrode and the conductive plug.

The semiconductor device may include a lower structure including a conductive plug, wherein the first lower electrode is on the conductive plug, the dielectric film is on the first lower electrode, and the second lower electrode is between the first lower electrode and the dielectric film.

The semiconductor device may include an insulating layer provided with an insulator layer opening, wherein the first lower electrode and the second lower electrode are on a side surface and a bottom surface of the opening, and the dielectric film and the first upper electrode are on the first lower electrode and the second lower electrode to fill the insulating layer opening.

Example embodiments provide a method of manufacturing a semiconductor device that may include forming a first lower electrode and a second lower electrode, the second lower electrode on at least a part of the first lower electrode using a material different from the first lower electrode, forming a dielectric film on at least a part of the second lower electrode, and forming a first upper electrode on the dielectric film.

The method may further include forming a second upper electrode on the dielectric film prior to forming the first upper electrode wherein the first upper electrode is formed on the second upper electrode.

Forming the first lower electrode and the second lower electrode may include forming a mold insulating layer provided with a mold insulating layer opening, forming the second lower electrode on a side surface and a bottom surface of the mold insulating layer opening, forming the first lower electrode on the second lower electrode in the mold insulating layer opening, and removing the mold insulating layer.

Forming the first lower electrode and the second lower electrode may include forming a mold insulating layer provided with a mold insulating layer opening, forming the first lower electrode to fill the mold insulating layer opening, removing the mold insulating layer, and forming a second lower electrode on the first lower electrode.

Forming the first lower electrode and the second lower electrode may include forming an insulating layer provided with an insulating layer opening, forming the first lower electrode and the second lower electrode to be sequentially disposed on a side surface and a bottom surface of the insulating layer opening, and laminating the dielectric film and the first upper electrode on the lower electrode in the insulating layer opening.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a diagram showing a first semiconductor device according to example embodiments.

FIG. 2 is a diagram showing a second semiconductor device according to example embodiments.

FIG. 3 is a diagram showing a third semiconductor device according to example embodiments.

FIG. 4 is a diagram showing a fourth semiconductor device according to example embodiments.

FIG. 5 is a diagram showing a fifth semiconductor device according to example embodiments.

FIGS. 6A and 6B are cross-sectional views illustrating example embodiments of a manufacturing method of a first semiconductor device according to example embodiments.

FIGS. 7A to 7F are cross-sectional views illustrating example embodiments of a manufacturing method of a third semiconductor device according to example embodiments.

FIGS. 8A to 8C are cross-sectional views illustrating example embodiments of a manufacturing method of a fourth semiconductor device according to example embodiments.

FIG. 9 is a cross-sectional view illustrating example embodiments of a manufacturing method of a fifth semiconductor device according to example embodiments.

FIG. 10 is a diagram showing the result of an experimental example where the thickness of an equivalent oxide film of a dielectric film is measured while the thickness of an SrRuO₃ layer varies.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

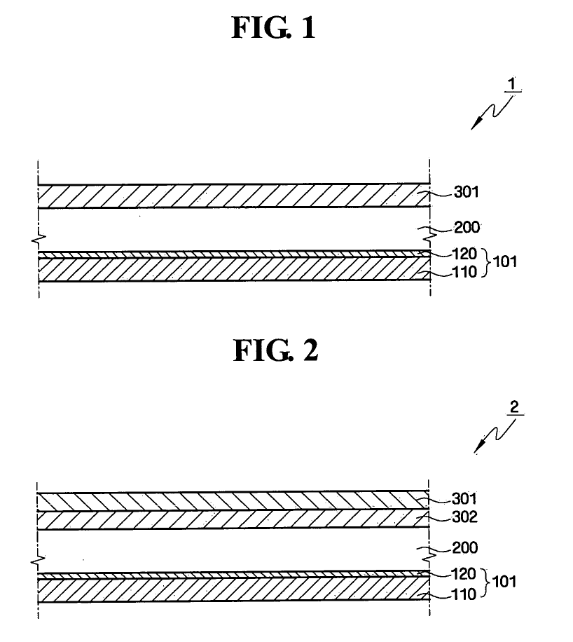

FIG. 1 is a diagram showing a first semiconductor device according to example embodiments.

Referring to FIG. 1, a semiconductor device 1 may include a lower electrode 101, a dielectric film 200 that is formed on the lower electrode 101, and a first upper electrode 301 that is formed on the dielectric film 200.

The lower electrode 101 may include a first lower electrode 110, and a second lower electrode 120 that is formed on the first lower electrode 110 using a material different from the first lower electrode 110.

The first lower electrode 110 may be formed of a material having a higher antioxidization and higher work function. The first lower electrode 110 may be a single film that is formed of a noble metal, such as Pt, Ru, or Ir, for example, a conductive noble metal oxide, such as PtO, RuO₂, or IrO₂, for example, a refractory metal, such as Ti, TiN, W, WN, Ta, TaN, HfN, ZrN, TiAlN, TaSiN, TiSiN, or TaAlN, for example, a composite film that is formed of two or more of Pt, Ru, Ir, PtO, RuO₂, IrO₂, Ti, TiN, W, WN, Ta, TaN, HfN, ZrN, TiAlN, TaSiN, TiSiN, and TaAlN, for example, or a laminate film of Pt, Ru, Ir, PtO, RuO₂, IrO₂, Ti, TiN, W, WN, Ta, TaN, HfN, ZrN, TiAlN, TaSiN, TiSiN, or TaAlN, for example.

The second lower electrode 120 may be formed on the first lower electrode 110. The second lower electrode 120 may be formed of a conductive oxide containing a material having a Perovskite crystal structure.

The Perovskite crystal structure may have the ABO₃ structure (where A and B are positive ions having different sizes), and may vary according to the ratio of A and B. For example, in a unit cell, A may be located at the corner, B may be located at the center, and the oxygen atom may be located at the edge of the unit cell. Various modifications of the Perovskite crystal structure may be obtained, for example according to materials for the B positive ion of the Perovskite crystal structure.

The second lower electrode 120 may be formed of, for example, SrRuO₃, CaRuO₃, (BaSr)RuO₃, LaNiO₃, (LaSr)CoO₃, (LaSr)MgO₃, or (LaSr)SnO₃.

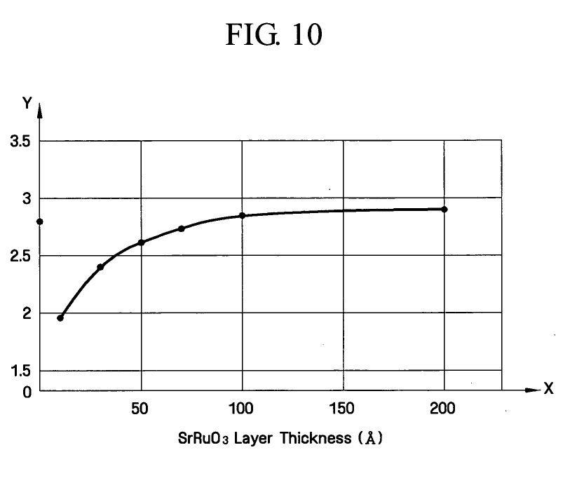

The second lower electrode 120 has a thickness smaller than the first lower electrode 110, the dielectric film 200, and the first upper electrode 301. For example, the thickness of the second lower electrode 120 may be in the range of about 3 to 70 Å. If the material of the second lower electrode 120 is a monomolecular layer, the thickness of the second lower electrode 120 may be approximately 3 Å. For example, if the second lower electrode 120 is formed of SrRuO₃, the second lower electrode 120 may have a thickness of approximately 3 Å, due to the lattice parameters of SrRuO₃. In addition, in an experimental example described below with reference to FIG. 10, the thickness of 70 Å corresponds to an inflection point where the thickness of an equivalent oxide film of the dielectric film 200, that is the Equivalent Oxide Thickness (EOT), may be reduced.

The thickness of the second lower electrode 120 may vary according to one or more conditions, such as temperature, pressure, and the like, and may be in a range of approximately 3 to 70 Å, a range of approximately 3 to 10 Å, or a range of approximately 10 to 50 Å, for example. Additional detail is provided by way of an experimental example with reference to FIG. 10.

The second lower electrode 120 may be interposed between the first lower electrode 110 and the dielectric film 200, so that a capacitor may be formed. The second lower electrode 120 may have a Perovskite crystal structure, and the structure of the second lower electrode 120 may be similar to the structure of the material for the dielectric film 200. Therefore, the interface characteristics between the second lower electrode 120 and the dielectric film 200 may be improved, which may improve the dielectric constant of the dielectric film 200.

The dielectric film 200 may be formed on the second lower electrode 120. The dielectric film 200 may be formed of a dielectric material having a Perovskite crystal structure, for example, and may be ferroelectric.

The dielectric film 200 may be formed of, for example, (BaSr)TiO₃, SrTiO₃, BaTiO₃, (PbZr)TiO₃, or (PbLaZr)TiO₃. Example embodiments using (BaSr)TiO₃ for the dielectric film 200 may have similar thermal and structural stability as SrTiO₃ and similar electrical characteristics as BaTiO₃.

The first upper electrode 301 may be formed on the dielectric film 200. The first upper electrode 301 may be formed of a material having a higher antioxidization and a higher work function. The first upper electrode 301 may be a single film that is formed of a noble metal, such as Pt, Ru, or Ir, for example, a conductive noble metal oxide, such as PtO, RuO₂, or IrO₂, for example, a refractory metal, such as Ti, TiN, W, WN, Ta, TaN, HfN, ZrN, TiAlN, TaSiN, TiSiN, or TaAlN, for example, or a laminate film of Pt, Ru, Ir, PtO, RuO₂, IrO_{2,} Ti, TiN, W, WN, Ta, TaN, HfN, ZrN, TiAlN, TaSiN, TiSiN, or TaAlN, for example.

FIG. 2 is a diagram showing a second semiconductor device according to example embodiments. Features illustrated in FIG. 1 are represented by the same reference numerals, and detailed descriptions thereof have been omitted.

Unlike example embodiments of the semiconductor device 1 illustrated in FIG. 1, a semiconductor device 2 according to example embodiments may include a second upper electrode 302 interposed between a dielectric film 200 and a first upper electrode 301.

The second upper electrode 302 may be formed of a conductive oxide, and may contain a material having a Perovskite crystal structure. For example, the second upper electrode 302 may be formed of SrRuO₃, CaRuO₃, (BaSr)RuO₃, LaNiO₃, (LaSr)CoO₃, (LaSr)MgO₃, or (LaSr)SnO₃.

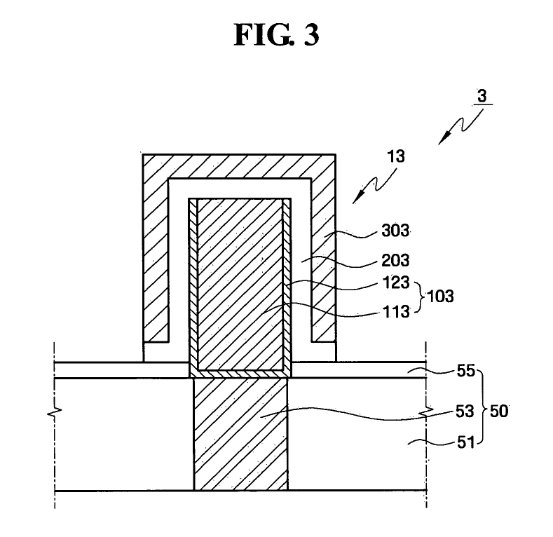

FIG. 3 is a diagram showing a third semiconductor device according to example embodiments. Features illustrated in FIGS. 1 and 2 are represented by the same reference numerals, and the detailed descriptions thereof have been omitted.

Referring to FIG. 3, a semiconductor device 3 according to example embodiments may include a lower structure 50, and a capacitor 13 that is formed on the lower structure 50. The capacitor 13 may be a stacked capacitor, and the stacked capacitor may have a dielectric film that is laminated on a convex lower electrode.

The lower structure 50 may include an interlayer insulating layer 51, an etching stopper layer 55 that is formed on the interlayer insulating layer 51, and a conductive plug 53 that is formed in the interlayer insulating layer 51. The interlayer insulating layer 51 may be formed of, for example, a silicon oxide (SiO₂), such as Plasma-Tetra Ethyl Ortho Silicate (P-TEOS), Undoped Silicate Glass (USG), or BoroPhospho Silicate Glass (BPSG). The etching stopper layer 55 may be formed of SiON or SiN. Additional example embodiments provide that the etching stopper layer 55 may be omitted.

The conductive plug 53 that is formed in the interlayer insulating layer 51 may electrically connect the second lower electrode 120 of the capacitor 13 to a conductive pattern (not shown in FIG. 3), which may be formed below the interlayer insulating layer 51. The conductive plug 53 may be a single film that is formed of one selected from a group including Ti, TiN, W, WN, Ru, Ta, TaN, HfN, ZrN, TiAlN, TaSiN, TiSiN, and TaAlN, for example, a composite film that is formed of two or more of Ti, TiN, W, WN, Ru, Ta, TaN, HfN, ZrN, TiAlN, TaSiN, TiSiN, and TaAlN, for example, or a laminate film of Ti, TiN, W, WN, Ru, Ta, TaN, HfN, ZrN, TiAlN, TaSiN, TiSiN, or TaAlN, for example.

The capacitor 13 may include a lower electrode 103, a dielectric film 203, and a first upper electrode 303. The lower electrode 103 may include a first lower electrode 113 and a second lower electrode 123.

The first lower electrode 113 may be formed on the conductive plug 53. The first lower electrode 113 may be a single film that is formed of a noble metal, such as Pt, Ru, or Ir, for example, a conductive noble metal oxide, such as PtO, RuO₂, or IrO₂, for example, a refractory metal, such as Ti, TiN, W, WN, Ta, TaN, HfN, ZrN, TiAlN, TaSiN, TiSiN, or TaAlN, for example, a composite film that is formed of two or more of Pt, Ru, Ir, PtO, RuO₂, IrO₂, Ti, TiN, W, WN, Ta, TaN, HfN, ZrN, TiAlN, TaSiN, TiSiN, and TaAlN for example, or a laminate film of Pt, Ru, Ir, PtO, RuO₂, IrO2, Ti, TiN, W, WN, Ta, TaN, HfN, ZrN, TiAlN, TaSiN, TiSiN, or TaAlN, for example.

The second lower electrode 123 may be interposed between a side surface of the first lower electrode 113 and the dielectric film 203. The second lower electrode 123 may be interposed between the first lower electrode 113 and the conductive plug 53. The second lower electrode 123 may be formed of a conductive oxide, and may have a Perovskite crystal structure. The second lower electrode 123 may be formed of, for example, SrRuO₃, CaRuO₃, (BaSr)RuO₃, LaNiO₃, (LaSr)CoO₃, (LaSr)MgO₃, or (LaSr)SnO₃. The thickness of the second lower electrode 123 may be in the range of approximately 3 to 70 Å.

The dielectric film 203 may be conformally formed on the lower electrode 103. The dielectric film 203 may be formed of a dielectric material having the Perovskite structure, such as (BaSr)TiO₃, SrTiO₃, BaTiO₃, (PbZr)TiO₃, or (PbLaZr)TiO₃, for example.

The first upper electrode 303 may be conformally formed on the dielectric film 203. The first upper electrode 303 may be formed of a material having higher antioxidization and a higher work function. The first upper electrode 303 may be a single film that is formed of a noble metal, such as Pt, Ru, or Ir, for example, a conductive noble metal oxide, such as PtO, RuO₂, or IrO₂, for example, a refractory metal, such as Ti, TiN, W, WN, Ta, TaN, HfN, ZrN, TiAlN, TaSiN, TiSiN, or TaAlN, for example, a composite film that is formed of two or more of Pt, Ru, Ir, PtO, RuO₂, IrO₂, Ti, TiN, W, WN, Ta, TaN, HfN, ZrN, TiAlN, TaSiN, TiSiN, or TaAlN, for example, or a laminate film of Pt, Ru, Ir, PtO, RuO₂, IrO₂, Ti, TiN, W, WN, Ta, TaN, HfN, ZrN, TiAlN, TaSiN, TiSiN, or TaAlN, for example.

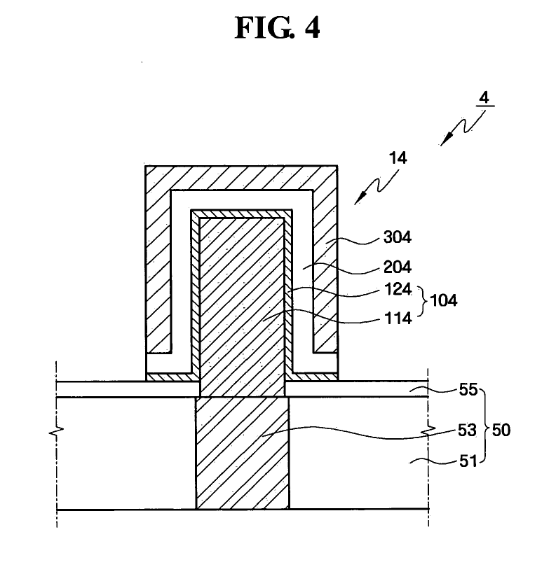

FIG. 4 is a diagram showing a fourth semiconductor device according to example embodiments. Features illustrated in FIGS. 1 through 3 are represented by the same reference numerals, and the detailed descriptions thereof will be omitted.

Referring to FIG. 4, unlike example embodiments of the capacitor 13 illustrated in FIG. 3, a capacitor 14 according to example embodiments may include a second lower electrode 124 that is not interposed between a first lower electrode 114 and a conductive plug 53.

For example, in capacitor 14 the first lower electrode 114 may be formed on the conductive plug 53 of the lower structure 50.

The second lower electrode 124 may be interposed between the first lower electrode 114 and the dielectric film 204. The second lower electrode 124 may be interposed between an etching stopper layer 55 and the dielectric film 204.

The dielectric film 204 and a first upper electrode 304 may be conformally formed on the second lower electrode 124. Unlike the example embodiments of the semiconductor device 3 illustrated in FIG. 3, in semiconductor device 4 the second lower electrode 124 may be formed on the top surface of the first lower electrode 114. The interface characteristics between the dielectric film 204 and the lower electrode 104 may be improved, and the dielectric constant of the dielectric film 204 may be improved.

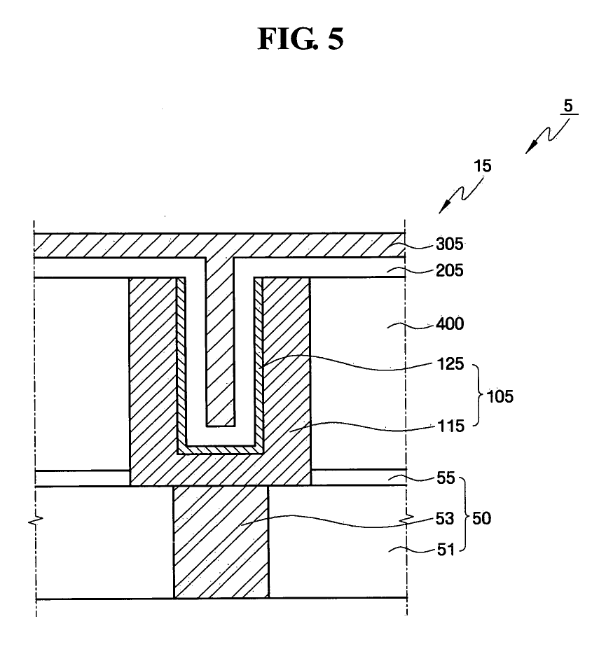

FIG. 5 is a diagram showing a fifth semiconductor device according to example embodiments. Features illustrated in FIGS. 1 through 4 are represented by the same reference numerals, and detailed descriptions thereof have been omitted.

Referring to FIG. 5, a semiconductor device 5 according to example embodiments may include a lower structure 50 and a capacitor 15 that is formed on the lower structure 50. The capacitor 15 may be a concave-shaped capacitor. The concave-shaped capacitor may have a dielectric film that is laminated on a concave lower electrode.

The capacitor 15 may include a lower electrode 105, a dielectric film 205, and a first upper electrode 305.

The lower electrode 105 may have a concave structure, that is, the lower electrode 105 may have a first lower electrode 115 and a second lower electrode 125 that are conformally laminated on a side surface and a bottom surface of an opening that is formed in an insulating layer 400. The second lower electrode 125 may be interposed between the first lower electrode 115 and the dielectric film 205. The insulating layer 400 may be a silicon oxide film, for example.

The dielectric film 205 may be conformally formed on the lower electrode 105 so as not to fill the opening of the insulating layer 400.

The first upper electrode 305 may be conformally formed on the dielectric film 205 so as to fill the opening of the insulating layer 400.

Although not shown in the example embodiments illustrated in FIGS. 3 through 5, example embodiments of third, fourth, and fifth semiconductor devices provide that a second upper electrode may be interposed between the dielectric film and the first upper electrode, as described with reference to FIG. 2.

Manufacturing methods of the semiconductor devices according to example embodiments will be described with reference to FIGS. 1 through 9B. It should be noted that in the following descriptions, detailed descriptions of techniques that are known to those skilled in the art may be omitted.

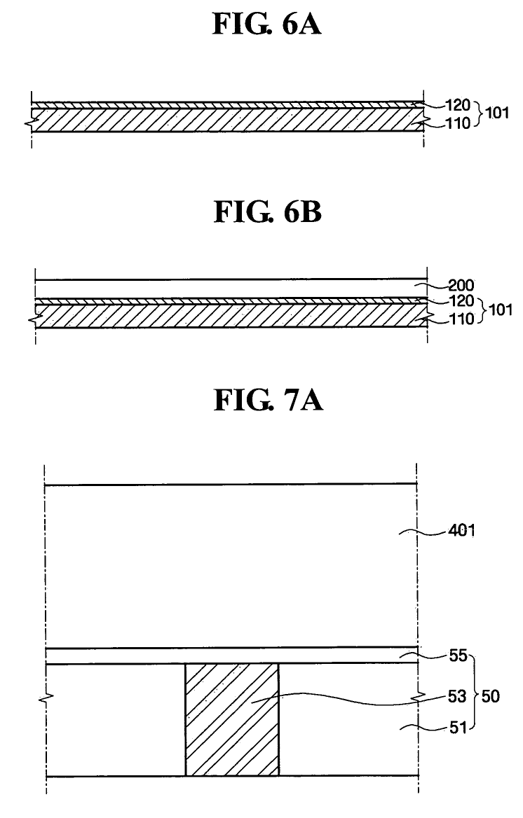

A manufacturing method of the first semiconductor device according to example embodiments will be described with reference to FIG. 1 and FIGS. 6A and 6B.

FIGS. 6A and 6B are cross-sectional views illustrating the manufacturing method of the first semiconductor device according example embodiments.

Referring to FIG. 6A, the lower electrode 101 that includes the first lower electrode 110 and the second lower electrode 120 may be formed.

Although not shown in FIG. 1, the first lower electrode 110 may be formed on an interlayer insulating layer (not shown) on a semiconductor substrate, in which an element (not shown), such as a transistor, may be formed.

The second lower electrode 120 may be formed of a conductive oxide, which may contain a material having a Perovskite crystal structure. The thickness of the second lower electrode 120 may be in a range of approximately 3 to 70 Å.

The second lower electrode 120 may be formed by Physical Vapor Deposition (PVD), Chemical Vapor Deposition (CVD), Metal Organic Vapor Deposition (MOCVD), Atomic Layer Deposition (ALD), or Plasma Enhanced ALD (PEALD). For example, the second lower electrode 120 may be formed by laminating SrRuO₃ at 300 to 500° C. for 4 to 15 seconds using PVD.

Referring to FIG. 6B, the dielectric film 200 may be formed on the second lower electrode 120. The dielectric film 200 may be formed of a dielectric material having a Perovskite crystal structure. The dielectric film 200 may be formed of, for example, (BaSr)TiO₃, SrTiO₃, BaTiO₃, (PbZr)TiO₃, or (PbLaZr)TiO₃.

For example, when a dielectric film 200 having the same crystal structure is laminated on the second lower electrode 120 having the Perovskite crystal structure, the interface characteristics between the second lower electrode 120 and the dielectric film 200 may be improved and the dielectric constant of the dielectric film 200 may be improved.

Referring to FIG. 1, the first upper electrode 301 may be formed on the dielectric film 200.

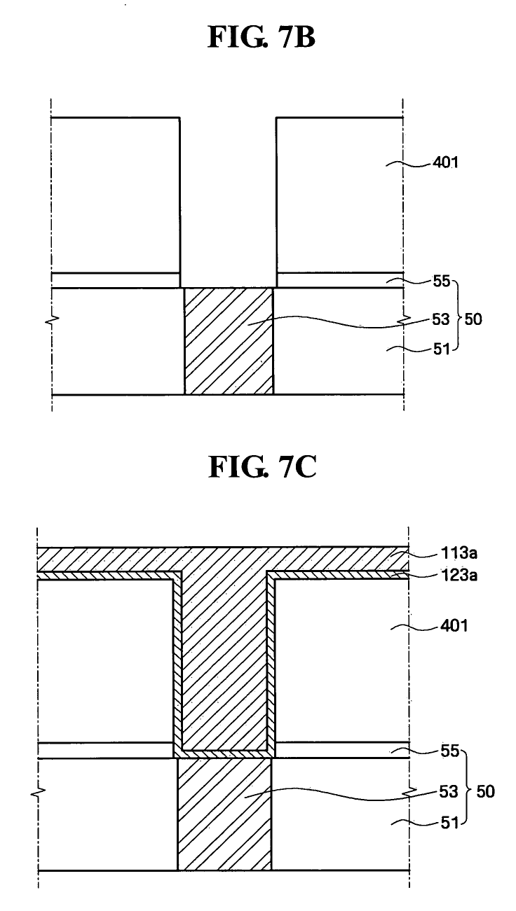

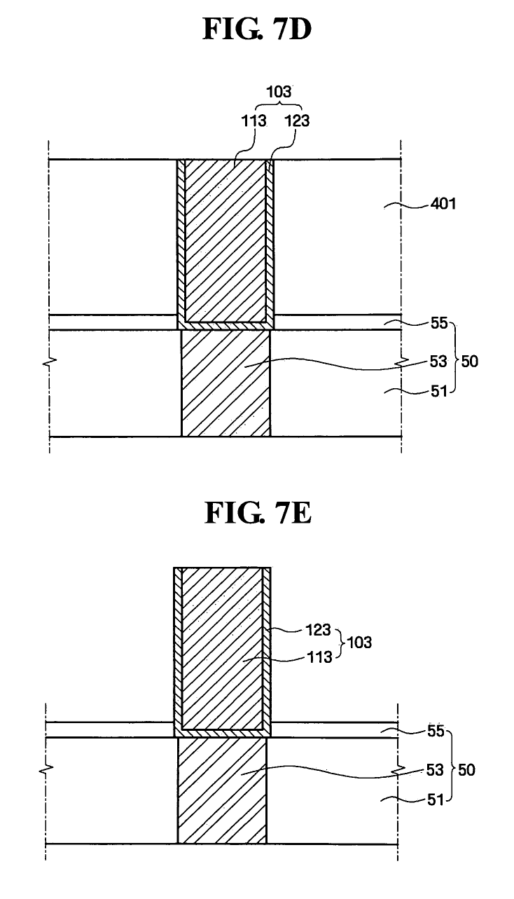

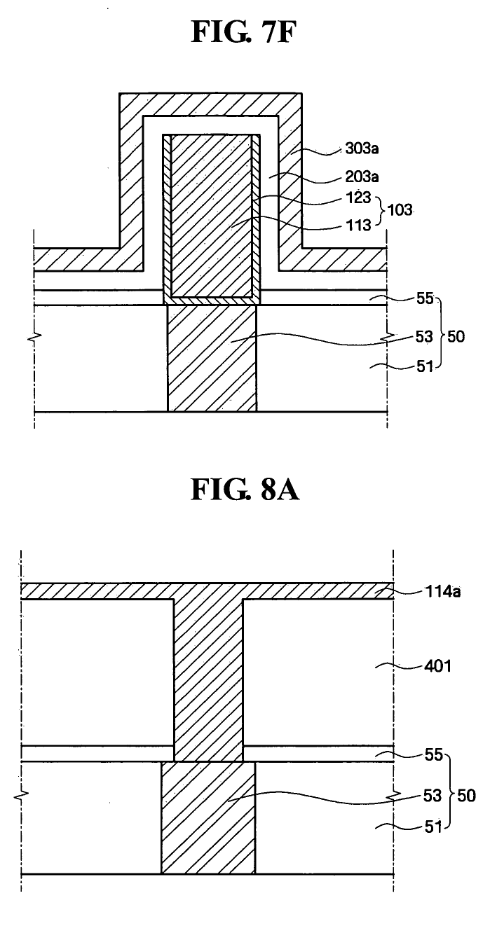

FIGS. 7A to 7F are cross-sectional views illustrating a manufacturing method of the third semiconductor device according to example embodiments.

Referring to FIG. 7A, a mold insulating layer 401 may be formed on the lower structure 50.

The lower structure 50 may be completed by forming the conductive plug 53 in the interlayer insulating layer 51 and forming the etching stopper layer 55 on the interlayer insulating layer 51.

A trench may be formed in the interlayer insulating layer 51. The interlayer insulating layer 51 may be formed of a silicon oxide, such as P-TEOS, USG, or BPSG, for example. The step of forming the trench in the interlayer insulating layer 51 may include the sub-steps of forming an etching mask on the interlayer insulating layer 51 to define the trench and etching the exposed interlayer insulating layer 51 through the etching mask.

The trench may be filled with a conductive material, and a planarization process, such as Chemical Mechanical Polishing (CMP) or etch-back, may be performed, thereby forming the conductive plug 53. The conductive plug 53 may be a single film that is formed of a conductive material, such as Ti, TiN, W, WN, Ta, TaN, HfN, ZrN, TiAlN, TaSiN, TiSiN, or TaAlN, for example, a composite film that is formed of two or more of Ti, TiN, W, WN, Ta, TaN, HfN, ZrN, TiAlN, TaSiN, TiSiN, or TaAlN, for example, or a laminate film of Ti, TiN, W, WN, Ta, TaN, HfN, ZrN, TiAlN, TaSiN, TiSiN, or TaAlN, for example.

The etching stopper layer 55 and the mold insulating layer 401 may be successively laminated on the interlayer insulating layer 51. The etching stopper layer 55 may be formed of, for example, SiON or SiN. Additional example embodiments provide that the etching stopper layer 55 may be omitted.

Referring to FIG. 7B, a portion of the mold insulating layer 401 that corresponds to the conductive plug 53 may be etched to form the opening.

Referring to FIG. 7C, a second lower electrode layer 123a and a first lower electrode layer 113a may be laminated in the opening.

The second lower electrode layer 123a may be conformally formed on the side surface and the bottom surface of the opening in the mold insulating layer 401. The first lower electrode layer 113a may be formed on the second lower electrode layer 123a in the opening of the mold insulating layer 401.

Referring to FIG. 7D, the first lower electrode layer 113a and the second lower electrode layer 123a may be removed by a planarization process, such as CMP or etch-back, and the lower electrode 103 may be formed.

Referring to FIG. 7E, the mold insulating layer 401 may be removed by a chemical etching process, such as Buffered Oxide Etching (BOE), and only the lower electrode 103 may remain on the interlayer insulating layer 51.

Referring to FIG. 7F, a dielectric film 203a and a first upper electrode layer 303a may be laminated on the lower electrode 103. For example, the dielectric film 203a may be formed by laminating the dielectric material having the Perovskite crystal structure described above to surround the lower electrode 103. Then, the first upper electrode layer 303a may be formed on the dielectric film 203a.

Referring to FIG. 3, the material for the dielectric film and the material for the first upper electrode may be removed, excluding portions corresponding to the dielectric film 203 and the first upper electrode 303 having vertical shapes, by patterning or etching, and the semiconductor device 3 may be completed.

A manufacturing method of the fourth semiconductor device according to example embodiments will be described with reference to FIGS. 4, 7A, 7B, and 8A through FIG. 8C.

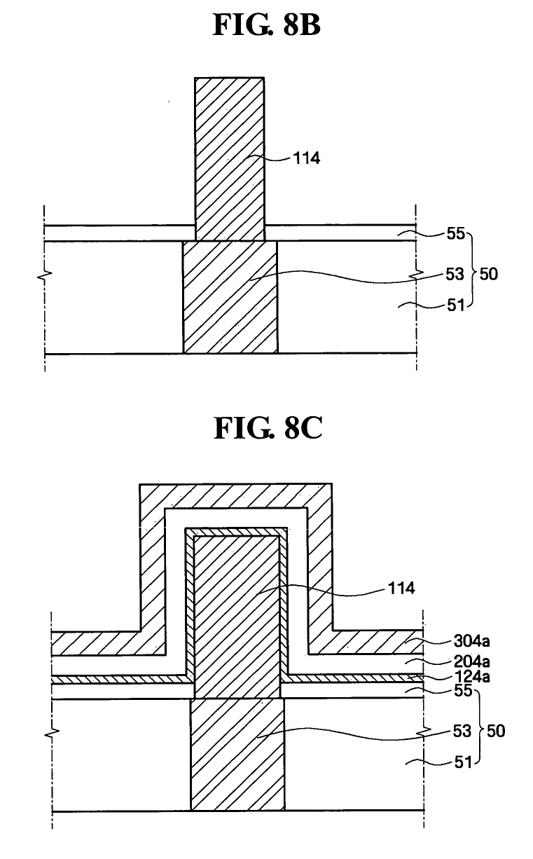

FIGS. 8A to 8C are cross-sectional views illustrating a manufacturing method of the fourth semiconductor device according to example embodiments.

Referring to FIG. 8A, as described with reference to FIGS. 7A and 7B, the opening may be formed in the mold insulating layer 401, and then a first lower electrode layer 114a may be formed to fill the opening of the mold insulating layer 401.

Referring to FIG. 8B, the material for the first lower electrode layer that is formed on the top surface of the mold insulating layer 401 may be removed by a planarization process, such as CMP or etch-back, and the first lower electrode 114 may be completed. The mold insulating layer 401 may be removed by a chemical etching process, such as BOE, such that only the first lower electrode 114 remains on the interlayer insulating layer 51, for example.

Referring to FIG. 8C, a second lower electrode layer 124a, a dielectric film 204a, and a first upper electrode layer 304a may be sequentially and/or conformally laminated on the first lower electrode 114. Example embodiments provide that, since the dielectric film 204 is formed on the entire surface of the second lower electrode layer 124a, the dielectric film 204a may be formed so as to have improved interface characteristics.

Referring to FIG. 4, the material for the second lower electrode, the material for the dielectric film, and the material for the upper electrode may be removed, excluding portions corresponding to the second lower electrode 124, the dielectric film 204, and the first upper electrode 304 having vertical shapes, by patterning or etching, and semiconductor device 4 may be formed.

A manufacturing method of the fifth semiconductor device according to example embodiments will be described with reference to FIGS. 5, 7A, 7B, and 9.

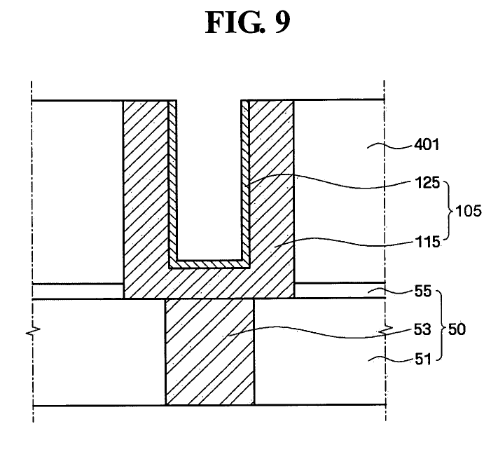

FIG. 9 is a cross-sectional view illustrating a manufacturing method of the fifth semiconductor device according to example embodiments shown in FIG. 5.

Referring to FIG. 9, as described above with reference to FIGS. 7A and 7B, the opening may be formed in the insulating layer 401, and the first lower electrode 115 and the second lower electrode 125 may be laminated on the side surface and the bottom surface of the opening in the insulating layer 401. The step of forming the first lower electrode 114 and the second lower electrode 125 may include sub-steps of successively laminating the first lower electrode layer and the second lower electrode layer in the trench and performing a planarization process, such as CMP or etch-back, so that the lower electrode 105 having a concave structure may be completed.

Referring to FIG. 5, the dielectric film 205 and the first upper electrode 305 may be sequentially laminated on the lower electrode 105 in the opening in the insulating layer 400, and the semiconductor device 5 may be formed. The dielectric film 205 and the first upper electrode 305 may be formed by PVD, CVD, MOCVD, ALD, or PEALD, for example. The dielectric film 205 and the first upper electrode 305 may be formed by CVD, MOCVD, ALD, or PEALD, for example, and improved step coatability may be realized.

Though not shown in the drawings, example embodiments of manufacturing methods that have been described above with reference to FIGS. 6A to 9 may further include a step of forming a second upper electrode on the dielectric film. For example, the first upper electrode may be formed on the second upper electrode.

Example embodiments provide the following specific example. Detailed descriptions of techniques that are known to those skilled in the art may be omitted.

### EXPERIMENTAL EXAMPLE

An Ru layer that serves as the first lower electrode may be formed to have a thickness of 200 Å, and an SrRuO₃ layer that serves as the second lower electrode may be formed on the first lower electrode. Next, a (BaSr)TiO₃ layer, an SrRuO₃ layer, and an Ru layer that serve as the dielectric film, the second upper electrode, and the first upper electrode may be formed on the second lower electrode to have a thickness of 200 Å, 200 Å, and 500 Å, respectively, and the capacitor may be completed. While the thickness of the SrRuO₃ layer serving as the second lower electrode varies, the thickness of the equivalent oxide film of the dielectric film is measured, the results of which are shown in Table 1 and FIG. 10.

Table 1 shows data of the experimental example where the thickness of the equivalent oxide film is measured while the thickness of the SrRuO₃ layer varies. In FIG. 9, the x-axis represents the thickness of the SrRuO₃ layer, and the y-axis represents the thickness of the equivalent oxide film.

TABLE 1
Thickness of SrRuO₃ Layer and Thickness of SrRuO₃ Layer

| | | | | | | | |
|---|---|---|---|---|---|---|---|
| Thickness of | 0 | 10 | 30 | 50 | 70 | 100 | 200 |
| SrRuO₃ Layer | | | | | | | |
| (Å) | | | | | | | |
| Thickness of | 2.80 | 1.96 | 2.42 | 2.64 | 2.72 | 2.85 | 2.91 |
| Equivalent Oxide | | | | | | | |
| Film (Å) | | | | | | | |

From this experimental example, it can be seen that, when the SrRuO3 layer serving as the second lower electrode is interposed between the Ru layer serving as the first lower electrode and the BaSrTiO₃ layer serving as the dielectric film to have a thickness of 3 to 70 Å, the thickness of the equivalent oxide film may be reduced compared with the case where the SrRuO₃ layer serving as the second lower electrode does not exist. That is, it can be seen that the dielectric constant of the dielectric film may be improved. Particularly, it can be seen that, when the SrRuO₃ layer is formed to have a thickness of in the range of about 10 to 50 Å, the thickness of the equivalent oxide film may be significantly reduced compared with the case where the SrRuO₃ layer serving as the second lower electrode is not formed.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor device, comprising:
a first lower electrode and a second lower electrode, the second lower electrode on at least a part of the first lower electrode and including a material different from the first lower electrode,
a dielectric film on at least a part of the second lower electrode, and
a first upper electrode on the dielectric film.

2. The semiconductor device of claim 1, wherein the thickness of the second lower electrode is in the range of 3 to 70 Å.

3. The semiconductor device of claim 1, wherein the thickness of the second lower electrode is in the range of 3 to 50 Å.

4. The semiconductor device of claim 1, wherein the thickness of the second lower electrode is in the range of 10 to 50 Å.

5. The semiconductor device of claim 1, wherein the second lower electrode is formed of SrRuO₃, and the dielectric film is formed of (BaSr)TiO₃ or SrTiO₃.

6. The semiconductor device of claim 5, wherein the first lower electrode is formed of Pt, Ru, or Ir.

7. The semiconductor device of claim 1, wherein the first lower electrode comprises a single film selected from the group consisting of Pt, Ru, Ir, PtO, RuO₂, IrO₂, Ti, TiN, W, WN, Ta, TaN, HfN, ZrN, TiAlN, TaSiN, TiSiN, and TaAlN, a composite film of two or more of Pt, Ru, Ir, PtO, RuO₂, IrO₂, Ti, TiN, W, WN, Ta, TaN, HfN, ZrN, TiAlN, TaSiN, TiSiN, and TaAlN, or a laminate film of Pt, Ru, Ir, PtO, RuO₂, IrO₂, Ti, TiN, W, WN, Ta, TaN, HfN, ZrN, TiAlN, TaSiN, TiSiN, or TaAlN.

8. The semiconductor device of claim 1, wherein the second lower electrode comprises a conductive oxide that contains at least one material with a Perovskite crystal structure.

9. The semiconductor device of claim 1, wherein the second lower electrode consists of a material selected from the group including SrRuO₃, CaRuO₃, (BaSr)RuO₃, LaNiO₃, (LaSr)CoO₃, (LaSr)MgO₃, and (LaSr)SnO₃.

10. The semiconductor device of claim 1, wherein the dielectric film comprises a dielectric material having a Perovskite crystal structure.

11. The semiconductor device of claim 1, wherein the dielectric film consists of a material selected from the group including (BaSr)TiO₃, SrTiO₃, BaTiO₃, (PbZr)TiO₃, and (PbLaZr)TiO₃.

12. The semiconductor device of claim 1, further comprising:
a second upper electrode interposed between the dielectric film and the first upper electrode.

13. A semiconductor device, comprising:
a lower structure including a conductive plug,
the semiconductor device of claim 1, wherein
the first lower electrode is on the conductive plug,
the dielectric film is on the first lower electrode, and
the second lower electrode is between a side surface of the first lower electrode and the dielectric film, and between the first lower electrode and the conductive plug.

14. A semiconductor device, comprising:
a lower structure including a conductive plug,
the semiconductor device of claim 1, wherein
the first lower electrode is on the conductive plug,
the dielectric film is on the first lower electrode, and
the second lower electrode is between the first lower electrode and the dielectric film.

15. A semiconductor device, comprising:
an insulating layer provided with an insulating layer opening,
the semiconductor device of claim 1, wherein
the first lower electrode and the second lower electrode are on a side surface and a bottom surface of the insulating layer opening, and
the dielectric film and the first upper electrode are on the first lower electrode and the second lower electrode to fill the insulating layer opening.

16. A method of manufacturing a semiconductor device, comprising:
forming a first lower electrode and a second lower electrode, the second lower electrode on at least a part of the first lower electrode using a material different from the first lower electrode,
forming a dielectric film on at least a part of the second lower electrode, and
forming a first upper electrode on the dielectric film.

17. The method of claim 16, wherein the thickness of the second lower electrode is in the range of 3 to 70 Å.

18. The method of claim 16, wherein the thickness of the second lower electrode is in the range of 3 to 50 Å.

19. The method of claim 16, wherein the thickness of the second lower electrode is in the range of 10 to 50 Å.

20. The method of claim 16, further comprising
forming a second upper electrode on the dielectric film prior to forming the first upper electrode and wherein
the first upper electrode is formed on the second upper electrode.

21. The method of claim 16, wherein forming the first lower electrode and the second lower electrode comprises:
forming a mold insulating layer provided with a mold insulating layer opening,
forming the second lower electrode on a side surface and a bottom surface of the mold insulating layer opening,
forming the first lower electrode on the second lower electrode in the mold insulating layer opening, and
removing the mold insulating layer.

22. The method of claim 16, wherein forming the first lower electrode and the second lower electrode comprises:
forming a mold insulating layer provided with a mold insulating layer opening,
forming the first lower electrode to fill the mold insulating layer opening,
removing the mold insulating layer, and
forming a second lower electrode on the first lower electrode.

23. The method of claim 16, wherein forming the first lower electrode and the second lower electrode comprises:
forming an insulating layer provided with an insulating layer opening,
forming the first lower electrode and the second lower electrode to be sequentially disposed on a side surface and a bottom surface of the insulating layer opening, and
laminating the dielectric film and the first upper electrode on the lower electrode in the insulating layer opening.
